(19) United States
(12) Patent Application Publication
(10) Pub. No.: US 2024/0394442 A1
(43) Pub. Date: Nov. 28, 2024

(54) MACHINE LEARNING WORKFLOW TO PREDICT TRUE SAND RESISTIVITY IN LAMINATED LOW RESISTIVITY SANDS

(71) Applicant: SAUDI ARABIAN OIL COMPANY, Dhahran (SA)

(72) Inventors: Yacine Meridji, Dhahran (SA); Lailaa Helmi Alshammasi, Dhahran (SA); Majed Fareed Kanfar, Dhahran (SA); Abdullah A. Alakeely, Dhahran (SA)

(73) Assignee: SAUDI ARABIAN OIL COMPANY, Dhahran (SA)

(21) Appl. No.: 18/323,224

(22) Filed: May 24, 2023

(51) Int. Cl. G06F 30/27; E21B 49/00; G06N 20/20

(52) U.S. Cl. CPC G06F 30/27; E21B 49/00; G06N 20/20; E21B 2200/20; E21B 2200/22

(57) ABSTRACT

A method and a system for predicting true sand resistivity in laminated low resistivity sands is disclosed. The method includes obtaining basic log values of laminated low resistivity sands and determining a volume of solids, a volume of fluids, and first reservoir parameters using a multimineral formation evaluation based on the basic log values of the laminated low resistivity sands. Further, a volume of sand, a volume of silt, a volume of clay, and a volume of shale are determined using a silty sand analysis based on the determined volume of solids, the determined volume of fluids, and the first determined reservoir parameters. Additionally, second determined parameters are inputted to a trained machine learning model to determine the true sand resistivity and the true sand resistivity is predicted using the trained machine learning model based on the second determined parameters.

### BACKGROUND

Low resistivity and low contrast zones are hydrocarbon-bearing reservoirs with the low resistivity or the low contrast in resistivity log responses, due to the influence of a plurality of factors associated with mineralogy, water salinity, and microporosity, as well as bed thickness, dip, and anisotropy. Presence of shale and silt in the hydrocarbon-bearing reservoirs significantly impacts the resistivity measurements by making the resistivity measurements lower compared to the true sand resistivity. Thinly laminated sands zones are anisotropic, where a horizontal resistivity (Rh) is controlled by conductive layers and a vertical resistivity (Rv) dominated by resistive hydrocarbon laminations. The low resistivity and low contrast laminated sand and silty sand evaluation embodies a short-term challenge, but a long term considerable upside for oil and gas operators.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In general, in one aspect, embodiments disclosed herein relate to a method for predicting true sand resistivity. The method includes obtaining basic log values of laminated low resistivity sands and determining a volume of solids, a volume of fluids, and first reservoir parameters using a multimineral formation evaluation based on the basic log values of the laminated low resistivity sands. Further, a volume of sand, a volume of silt, a volume of clay, and a volume of shale are determined using a silty sand analysis based on the determined volume of solids, the determined volume of fluids, and the first determined reservoir parameters. Additionally, second determined parameters are inputted to a trained machine learning model to determine the true sand resistivity and the true sand resistivity is predicted using the trained machine learning model based on the second determined parameters.

In general, in one aspect, embodiments disclosed herein relate to a system including a well logging system for obtaining basic log values of laminated low resistivity sands, and a true sand resistivity simulator comprising a computer processor. Further, the computer processor comprises functionality for determining a volume of solids, a volume of fluids, and first reservoir parameters using a multimineral formation evaluation based on the basic log values of the laminated low resistivity sands. Further the computer processor comprises functionality for determining, a volume of sand, a volume of silt, a volume of clay, and a volume of shale using a silty sand analysis based on the determined volume of solids, the determined volume of fluids, and the first determined reservoir parameters. Additionally, second determined parameters are inputted to a trained machine learning model to determine the true sand resistivity and the true sand resistivity is predicted using the trained machine learning model based on the second determined parameters.

In general, in one aspect, embodiments disclosed herein relate to a non-transitory computer readable medium storing a set of instructions executable by a computer processor, the set of instructions including the functionality for obtaining basic log values of laminated low resistivity sands and determining a volume of solids, a volume of fluids, and first reservoir parameters using a multimineral formation evaluation based on the basic log values of the laminated low resistivity sands. Further, a volume of sand, a volume of silt, a volume of clay, and a volume of shale are determined using a silty sand analysis based on the determined volume of solids, the determined volume of fluids, and the first determined reservoir parameters. Additionally, second determined parameters are inputted to a trained machine learning model to determine the true sand resistivity and the true sand resistivity is predicted using the trained machine learning model based on the second determined parameters.

Other aspects and advantages of the claimed subject matter will be apparent from the following description and the appended claims.

### BRIEF DESCRIPTION OF DRAWINGS

Specific embodiments disclosed herein will now be described in detail with reference to the accompanying figures. Like elements in the various figures are denoted by like reference numerals for consistency. Like elements may not be labeled in all figures for the sake of simplicity.

FIG. 1 shows a system in accordance with one or more embodiments.

FIG. 2 shows a flowchart in accordance with one or more embodiments.

FIG. 3 shows a workflow for performing multimineral formation evaluation and silty sand analysis and determining the true sand resistivity in accordance with one or more embodiments.

FIG. 4 shows a graph of predicted and measured true sand resistivity in accordance with one or more embodiments.

FIG. 5 shows a computer system in accordance with one or more embodiments.

### DETAILED DESCRIPTION

In the following detailed description of embodiments disclosed herein, numerous specific details are set forth in order to provide a more thorough understanding disclosed herein. However, it will be apparent to one of ordinary skill in the art that the invention may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers does not imply or create a particular ordering of the elements or limit any element to being only a single element unless expressly disclosed, such as by the use of the terms “before,” “after,” “single,” and other such terminology. Rather, the use of ordinal numbers is to distinguish between the elements. By way of an example, a first element is distinct from a second element, and the first element may encompass more than one element and succeed (or precede) the second element in an ordering of elements.

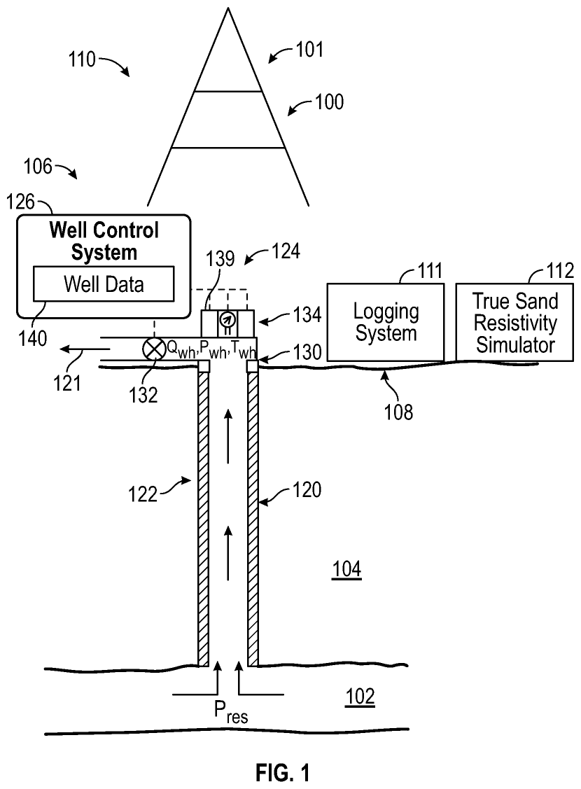

In the following description of FIGS. 1-5, any component described with regard to a figure, in various embodiments disclosed herein, may be equivalent to one or more like-named components described with regard to any other figure. For brevity, descriptions of these components will not be repeated with regard to each figure. Thus, each and every embodiment of the components of each figure is incorporated by reference and assumed to be optionally present within every other figure having one or more like-named components. Additionally, in accordance with various embodiments disclosed herein, any description of the components of a figure is to be interpreted as an optional embodiment which may be implemented in addition to, in conjunction with, or in place of the embodiments described with regard to a corresponding like-named component in any other figure.

It is to be understood that the singular forms “a,” “an,” and “the” include plural referents unless the context clearly dictates otherwise. Thus, for example, reference to “a horizontal beam” includes reference to one or more of such beams.

Terms such as “approximately,” “substantially,” etc., mean that the recited characteristic, parameter, or value need not be achieved exactly, but that deviations or variations, including for example, tolerances, measurement error, measurement accuracy limitations and other factors known to those of skill in the art, may occur in amounts that do not preclude the effect the characteristic was intended to provide.

It is to be understood that one or more of the steps shown in the flowcharts may be omitted, repeated, and/or performed in a different order than the order shown. Accordingly, the scope disclosed herein should not be considered limited to the specific arrangement of steps shown in the flowcharts.

Although multiple dependent claims are not introduced, it would be apparent to one of ordinary skill that the subject matter of the dependent claims of one or more embodiments may be combined with other dependent claims.

Embodiments disclosed herein provide a method and system for predicting true sand resistivity in laminated low resistivity sands. Specifically, the method predicts the true sand resistivity in the laminated low resistivity sands of a hydrocarbon bearing reservoir when advanced tri-axial resistivity logs are not available. Conventional resistivity logs, by design, result in higher water saturation in laminated sands, due to the laminated high anisotropy nature of the rock. Further, the induction tools show the interbedded sand and shale sequences to have the same low resistivity resulting in a reduced hydrocarbon pore volume in place. The determination is based on basic Gamma-ray-Resistivity-Density-Neutron-sonic logs.

Further, embodiments disclosed herein enable a user to predict accurate true sand resistivity, which enables estimating water saturation and hydrocarbon reserves, in areas where tri-axial induction tools are not available. Therefore, this disclosure aims to provide a machine learning based solution for predicting true sand resistivity in laminated low resistivity sands. A user may use embodiments described herein to go back in time even before the technology's introduction in early 2000's and generate the synthetic Rsand logs from basic quad-combo data. The proposed method is reliable and results in a significant increase in estimated hydrocarbon pore volume.

FIG. 1 shows a schematic diagram in accordance with one or more embodiments. As shown in FIG. 1, a well environment (100) includes a hydrocarbon reservoir (“reservoir”) (102) located in a subsurface hydrocarbon-bearing formation (“formation”) (104) and a well system (106). The hydrocarbon-bearing formation (104) may include a porous or fractured rock formation that resides underground, beneath a geological surface (“surface”) (108). In the case of the well system (106) being a hydrocarbon well, the reservoir (102) may include a portion of the hydrocarbon-bearing formation (104). The hydrocarbon-bearing formation (104) and the reservoir (102) may include different layers of rock having varying characteristics, such as varying degrees of permeability, porosity, capillary pressure, and resistivity. In the case of the well system (106) being operated as a production well, the well system (106) may facilitate the extraction of hydrocarbons (or “production”) from the reservoir (102).

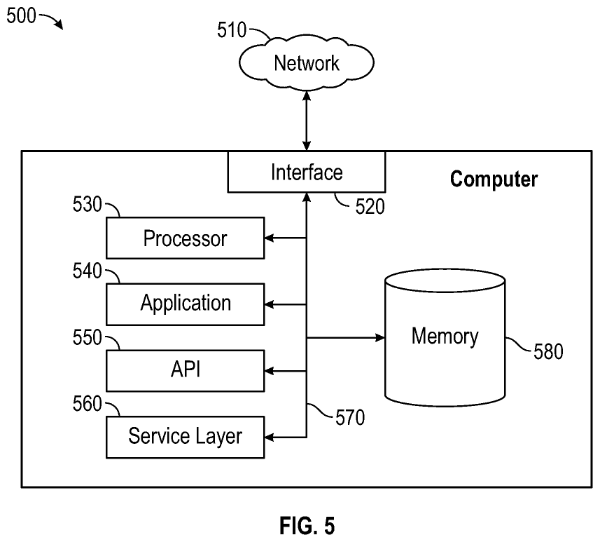

In some embodiments, the well system (106) includes a rig (101), a drilling system (110), a logging system (111), a true sand resistivity simulator (112), a wellbore (120), a well sub-surface system (122), a well surface system (124), and a well control system (“control system”) (126). The drilling system (110) may include a drill string, a drill bit, and a mud circulation system for use in drilling the wellbore (120) into the formation (104). The logging system (111) may include one or more logging tools, for use in generating well logs, based on the sensing system (134), of the formation (104). The well control system (126) may control various operations of the well system (106), such as well production operations, well drilling operation, well completion operations, well maintenance operations, and reservoir monitoring, assessment and development operations. In some embodiments, the well control system (126) includes a computer system that is the same as or similar to that of a computer system (500) described below in FIG. 5 and the accompanying description.

The rig (101) is a combination of equipment used to drill a borehole to form the wellbore (120). Major components of the rig (101) include the drilling fluid tanks, the drilling fluid pumps (e.g., rig mixing pumps), the derrick or mast, the draw works, the rotary table or top drive, the drill string, the power generation equipment and auxiliary equipment.

The wellbore (120) includes a bored hole (i.e., borehole) that extends from the surface (108) into a target zone of the hydrocarbon-bearing formation (104), such as the reservoir (102). An upper end of the wellbore (120), terminating at or near the surface (108), may be referred to as the “up-hole” end of the wellbore (120), and a lower end of the wellbore, terminating in the hydrocarbon-bearing formation (104), may be referred to as the “downhole” end of the wellbore (120). The wellbore (120) may facilitate the circulation of drilling fluids during drilling operations, flow of hydrocarbon production (“production”) (121) (e.g., oil and gas) from the reservoir (102) to the surface (108) during production operations, the injection of substances (e.g., water) into the hydrocarbon-bearing formation (104) or the reservoir (102) during injection operations, or the communication of monitoring devices (e.g., logging tools) lowered into the hydrocarbon-bearing formation (104) or the reservoir (102) during monitoring operations (e.g., during in situ logging operations).

In some embodiments, during operation of the well system (106), the well control system (126) collects and records well data (140) for the well system (106). During drilling operation of the well (106), the well data (140) may include mud properties, flow rates measured by a flow rate sensor (139), drill volume and penetration rates, formation characteristics, etc. To drill a subterranean well or wellbore (120), a drill string (110), including a drill bit and drill collars to weight the drill bit, may be inserted into a pre-drilled hole and rotated to cut into the rock at the bottom of the hole, producing rock cuttings. Commonly, the drilling fluid, or drilling mud, may be utilized during the drilling process. To remove the rock cuttings from the bottom of the wellbore (120), drilling fluid is pumped down through the drill string (110) to the drill bit. The drilling fluid may cool and lubricate the drill bit and provide hydrostatic pressure in the wellbore (120) to provide support to the sidewalls of the wellbore (120). The drilling fluid may also prevent the sidewalls from collapsing and caving in on the drill string (110) and prevent fluids in the downhole formations from flowing into the wellbore (120) during drilling operations. Additionally, the drilling fluid may lift the rock cuttings away from the drill bit and upwards as the drilling fluid is recirculated back to the surface. The drilling fluid may transport rock cuttings from the drill bit to the surface, which can be referred to as “cleaning” the wellbore (120), or hole cleaning.

In some embodiments, the well data (140) are recorded in real-time, and are available for review or use within seconds, minutes or hours of the condition being sensed (e.g., the measurements are available within 1 hour of the condition being sensed). In such an embodiment, the well data (140) may be referred to as “real-time” well data (140). Real-time well data (140) may enable an operator of the well (106) to assess a relatively current state of the well system (106), and make real-time decisions regarding a development of the well system (106) and the reservoir (102), such as on-demand adjustments in drilling fluid and regulation of production flow from the well.

In some embodiments, the well surface system (124) includes a wellhead (130). The wellhead (130) may include a rigid structure installed at the “up-hole” end of the wellbore (120), at or near where the wellbore (120) terminates at the geological surface (108). The wellhead (130) may include structures for supporting (or “hanging”) casing and production tubing extending into the wellbore (120). Production (121) may flow through the wellhead (130), after exiting the wellbore (120) and the well sub-surface system (122), including, for example, the casing and the production tubing. In some embodiments, the well surface system (124) includes flow regulating devices that are operable to control the flow of substances into and out of the wellbore (120). For example, the well surface system (124) may include one or more production valves (132) that are operable to control the flow of production (121). For example, a production valve (132) may be fully opened to enable the unrestricted flow of production (121) from the wellbore (120), the production valve (132) may be partially opened to partially restrict (or “throttle”) the flow of production (121) from the wellbore (120), and production valve (132) may be fully closed to fully restrict (or “block”) the flow of production (121) from the wellbore (120), and through the well surface system (124).

In some embodiments, the wellhead (130) includes a choke assembly. For example, the choke assembly may include hardware with functionality for opening and closing the fluid flow through pipes in the well system (106). Likewise, the choke assembly may include a pipe manifold that may lower the pressure of fluid traversing the wellhead. As such, the choke assembly may include a set of high-pressure valves and at least two chokes. These chokes may be fixed or adjustable or a mix of both. Redundancy may be provided so that if one choke has to be taken out of service, the flow can be directed through another choke. In some embodiments, pressure valves and chokes are communicatively coupled to the well control system (126). Accordingly, a well control system (126) may obtain wellhead data regarding the choke assembly as well as transmit one or more commands to components within the choke assembly in order to adjust one or more choke assembly parameters.

Keeping with FIG. 1, in some embodiments, the well surface system (124) includes a surface sensing system (134). The surface sensing system (134) may include sensors for sensing characteristics of substances, including production (121), passing through or otherwise located in the well surface system (124). The characteristics may include, for example, pressure, temperature and flow rate of production (121) flowing through the wellhead (130), or other conduits of the well surface system (124), after exiting the wellbore (120). The surface sensing system (134) may also include sensors for sensing characteristics of the rig (101), such as bit depth, hole depth, drilling fluid flow, hook load, rotary speed, etc.

In some embodiments, the well system (106) includes the true sand resistivity simulator (112). For example, the true sand resistivity simulator (112) may include hardware and/or software with functionality for generating one or more reservoir models regarding the hydrocarbon-bearing formation (104) and/or performing one or more reservoir simulations. For example, the true sand resistivity simulator (112) may store the basic well logs, parameters determined using the multimineral formation evaluation and silty sand analysis. For this purpose, the simulator may include memory with one or more data structures, such as a buffer, a table, an array, or any other suitable storage medium. The true sand resistivity simulator (112) may further, at least, analyze the basic well logs, perform the multimineral formation evaluation, perform the silty sand analysis and determine the true sand resistivity. While true sand resistivity simulator (112) is shown at a well site, in some embodiments, the true sand resistivity simulator (112) may be located remotely from well site. In some embodiments, true sand resistivity simulator (112) may include a computer system that is similar to the computer system (500) described below with regard to FIG. 5 and the accompanying description.

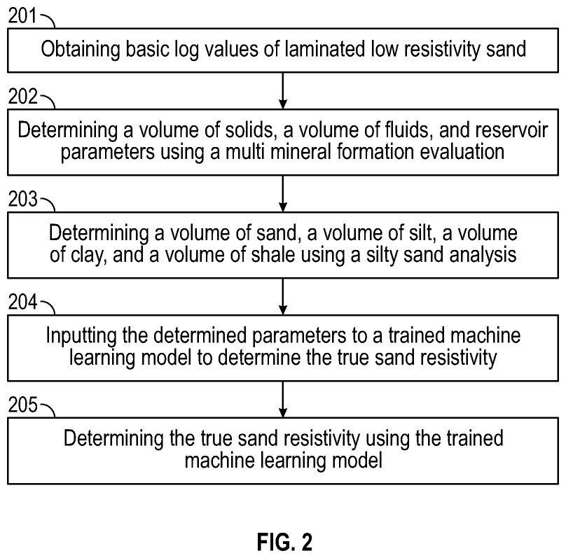

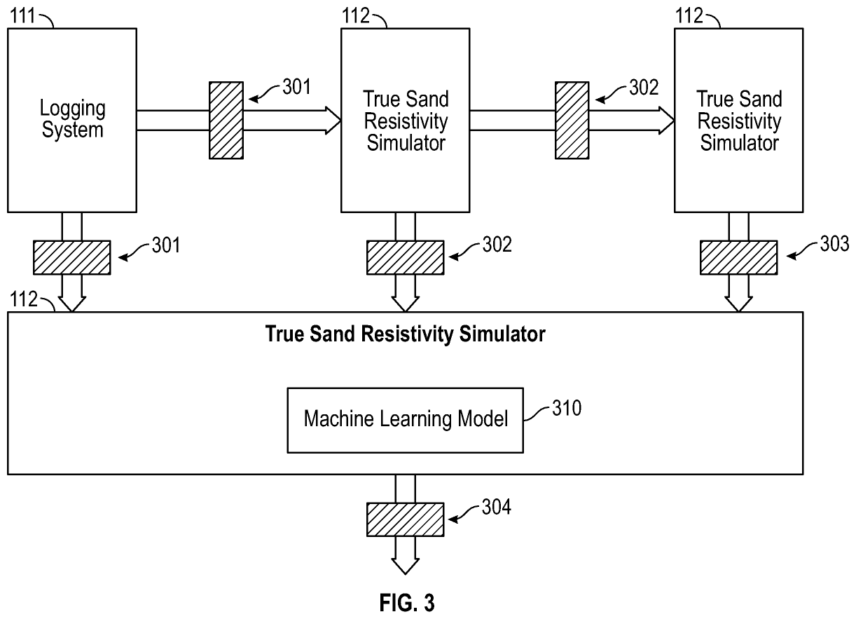

FIG. 2 shows a flowchart in accordance with one or more embodiments for determining predicting true sand resistivity in laminated low resistivity sands. Specifically, in Block 201, basic gamma-ray logs, resistivity logs, density logs, neutron porosity logs, compressional sonic logs, shear sonic logs, and velocity radio logs are obtained. In one or more embodiments the basic logs may be obtained in real-time. As shown in FIG. 3, the basic logs (301) present a detailed numerical description of the gamma-ray, resistivity, density, neutron porosity, and sonic logs over a reservoir depth. In one or more embodiments, the gamma-ray logs, resistivity logs, density logs, neutron porosity logs, compressional sonic logs, shear sonic logs, and velocity radio logs may be obtained simultaneously during drilling operations, in real-time. In other embodiments, the gamma-ray, resistivity, density, neutron porosity, and sonic logs may be obtained sequentially or immediately after drilling operations are performed. The basic logs (301) may be obtained by the logging system (111) which may include one or more logging tools used for the formation (104)

Further, in Block 202, a multimineral formation evaluation (302) is performed on the obtained basic log values (301) of laminated low resistivity sands. As shown in FIG. 3, the multimineral formation evaluation (302) provides the volume of solids, fluids, and other formation parameters at each depth level by solving an opportune cost function that expresses the distance between the observed measurements and the predictions of the model chosen to describe the system. In one or more embodiments, the formation parameters include porosity, permeability, fluid saturation, grain density, formation factor, resistivity index, capillary pressure, etc. The multimineral formation evaluation (302) includes a system parameterization, which defines the set of parameters of unknown volumes which characterize the formation, a direct modeling, which involves linear and/or nonlinear laws able to generate the synthetic values for the observed parameters, and after the parameters describing the model are fixed, an inverse modeling, which determines the volumetric quantification of the solids, the fluids and the other parameters.

Further, in Block 203, a silty sand analysis is performed on the volume of solids, fluids, and other parameters. As shown on FIG. 3, the silty sand analysis (303) provides a volume of sand, a volume of silt, a volume of clay, and a volume of shale by employing a computer-assisted soil volumetric analysis. The computer-assisted soil volumetric analysis is based on Silt-Sand-Clay model that requires that requires neutron porosity log, bulk density, hydrocarbon density and brine density. The model obtains end points including a quartz point, a water point, wet and dry silt points, and wet and dry clay points. The analyst adjusts the end points to obtain the volume of sand, the volume of silt, the volume of clay, and the volume of shale.

In Block 204, and as shown in FIG. 3, the obtained basic logs (301), the results of multimineral formation evaluation (302), and the results of the silty sand analysis (303) are inputted to a trained machine learning (ML) model (310) to obtain a true sand resistivity (304). That is, the trained ML model uses the results of the analyses performed in FIG. 3 as inputs to predict or determine true sand resistivity (304). As used herein, ML (310) may include various machine learning algorithms or models suitable to predict or determine data such as true sand resistivity (304). In some embodiments, the true sand resistivity simulator (112) includes hardware and/or software with functionality for generating and/or updating one or more machine-learning models (310) to determine conventional multimineral formation evaluation (302), silty sand analysis (303), and true sand resistivity (304). Examples of machine-learning models (310) may include artificial neural networks, such as convolutional neural networks, deep neural networks, and recurrent neural networks. Machine-learning models (310) may also include support vector machines, decision trees, inductive learning models, deductive learning models, supervised learning models, unsupervised learning models, reinforcement learning models, etc. The machine learning models (310) used in this disclosure may be, for example at least, ResNET, Xception, VGG16, DenseNET, and EfficientNET. In a deep neural network, for example, a layer of neurons may be trained on a predetermined list of features based on the previous network layer's output. Thus, as data progresses through the deep neural network, more complex features may be identified within the data by neurons in later layers. Likewise, a U-net model or other type of convolutional neural network model may include various convolutional layers, pooling layers, fully connected layers, and/or normalization layers to produce a particular type of output. Thus, convolution and pooling functions may be the activation functions within a convolutional neural network.

In some embodiments, two or more different types of machine-learning models (310) are integrated into a single machine-learning architecture, e.g., a machine-learning model (310) may include support vector machines and neural networks. In some embodiments, the true sand resistivity simulator (112) may generate augmented data or synthetic data to produce a large amount of interpreted data for training a particular model. In some embodiments, various types of machine learning algorithms (310) may be used to train the model, such as a backpropagation algorithm. In a backpropagation algorithm, gradients are computed for each hidden layer of a neural network in reverse from the layer closest to the output layer proceeding to the layer closest to the input layer. As such, a gradient may be calculated using the transpose of the weights of a respective hidden layer based on an error function (also called a “loss function”). The error function may be based on various criteria, such as mean squared error function, a similarity function, etc., where the error function may be used as a feedback mechanism for tuning weights in the machine-learning model.

With respect to artificial neural networks, for example, an artificial neural network may include one or more hidden layers, where a hidden layer includes one or more neurons. A neuron may be a modelling node or object that is loosely patterned on a neuron of the human brain. In particular, a neuron may combine data inputs with a set of coefficients, i.e., a set of network weights for adjusting the data inputs. These network weights may amplify or reduce the value of a particular data input, thereby assigning an amount of significance to various data inputs for a task being modeled. Through machine learning (310), a neural network may determine which data inputs should receive greater priority in determining one or more specified outputs of the artificial neural network. Likewise, these weighted data inputs may be summed such that this sum is communicated through a neuron's activation function to other hidden layers within the artificial neural network. As such, the activation function may determine whether and to what extent an output of a neuron progresses to other neurons where the output may be weighted again for use as an input to the next hidden layer.

In one or more embodiments, the trained machine learning model (310) for the analysis of the obtained basic logs (301), the results of multimineral formation evaluation (302), and the results of the silty sand analysis (303) is a Random Forest based on the best root-mean-square-error (RMSE). The Random Forest is used for obtaining non-linear relationships between input features and the target variable. In one or more embodiments, XGBoost, SVM and neural networks may be used as the trained machine learning model (310).

Further, in Block 205 the trained ensemble Random Forest model uses the obtained basic logs (301), the results of multimineral formation evaluation (302), and the results of the silty sand analysis (303) are inputted to a trained machine learning (ML) model (310) to obtain a true sand resistivity (304). The true resistivity of the sand (304) characterizes its ability to oppose the passage of a current. It affects various fields such as electric power systems, electronics, environmental, geotechnical, groundwater, agriculture, and underground resource exploration.

The sand may be homogeneous and isotropic when the resistivity is equal at any point and direction. However, homogeneous soils are very rare. Usually, there are variations in resistivity both laterally and in-depth due to a type of sand, a material mixture, salt concentration, pH levels, temperature, porosity, etc. Further, the determined true sand resistivity (304) values may be validated by a blind testing in the nearby wells and comparing the measured true sand resistivity values with the determined true sand resistivity values.

This machine learning model (310) is applicable to both oil and gas reservoirs. However, it is generally applicable to the vertical wells, as the tri-axial resistivity logs are not acquired in horizontal wells. Further, this model is applicable to vertical or deviated low resistivity laminated sands and to low resistivity high anisotropy zones.

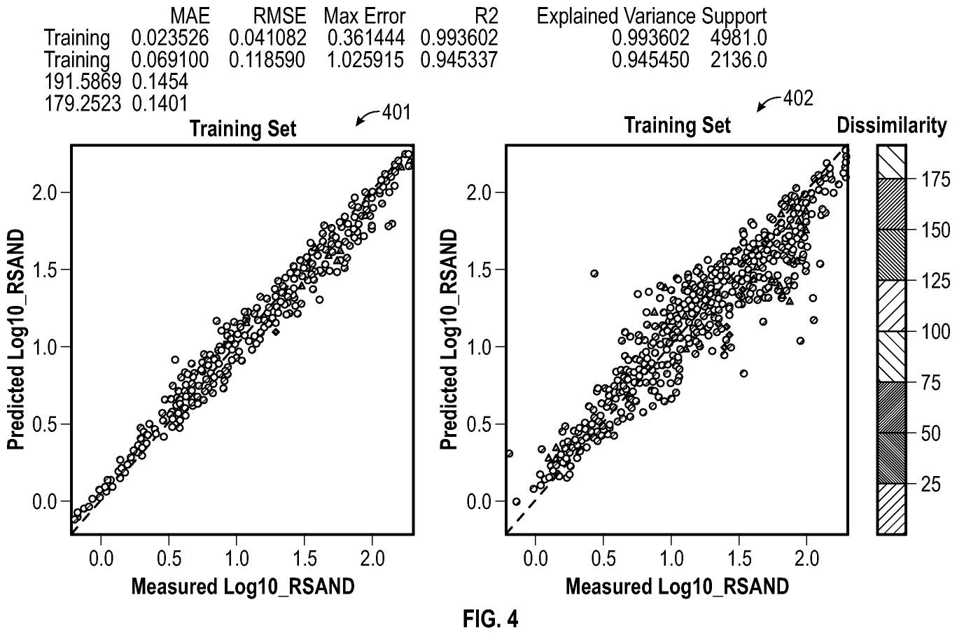

FIG. 4 shows a graph describing a similarity between the predicted true sand resistivity and the measured true sand resistivity on a training set (401) and a testing set (402). In this example, a several wells were used to train the machine-learning model. After reaching the lowest acceptable RMSE error, the model was deployed in multiple wells across the same field to benchmark against the measured logs. Additionally, the newly drilled wells were included in the blind testing phase to ensure prediction accuracy.

In FIG. 4, the x-axis of the graph represents the measured true sand resistivity, and the y-axis represents the predicted true sand resistivity. The graph shows results had excellent match with formation evaluation results from measured data. Specifically, the mean absolute error for the training set (401) is 2.35% and the mean absolute error for the testing set is 6.91%.

Embodiments disclosed herein may be implemented on any suitable computing device, such as the computer system shown in FIG. 5. Specifically, FIG. 5 is a block diagram of a computer system (500) used to provide computational functionalities associated with described algorithms, methods, functions, processes, flows, and procedures as described in the instant disclosure, according to an implementation. The illustrated computer (500) is intended to encompass any computing device such as a high performance computing (HPC) device, a server, desktop computer, laptop/notebook computer, wireless data port, smart phone, personal data assistant (PDA), tablet computing device, one or more processors within these devices, or any other suitable processing device, including both physical or virtual instances (or both) of the computing device. Additionally, the computer (500) may include a computer that includes an input device, such as a keypad, keyboard, touch screen, or other device that can accept user information, and an output device that conveys information associated with the operation of the computer (500), including digital data, visual, or audio information (or a combination of information), or a GUI.

The computer (500) can serve in a role as a client, network component, a server, a database or other persistency, or any other component (or a combination of roles) of a computer system for performing the subject matter described in the instant disclosure. The illustrated computer (500) is communicably coupled with a network (510). In some implementations, one or more components of the computer (500) may be configured to operate within environments, including cloud-computing-based, local, global, or other environment (or a combination of environments).

At a high level, the computer (500) is an electronic computing device operable to receive, transmit, process, store, or manage data and information associated with the described subject matter. According to some implementations, the computer (500) may also include or be communicably coupled with an application server, e-mail server, web server, caching server, streaming data server, business intelligence (BI) server, or other server (or a combination of servers).

The computer (500) can receive requests over network (510) from a client application (for example, executing on another computer (500) and responding to the received requests by processing the said requests in an appropriate software application. In addition, requests may also be sent to the computer (500) from internal users (for example, from a command console or by other appropriate access method), external or third-parties, other automated applications, as well as any other appropriate entities, individuals, systems, or computers.

Each of the components of the computer (500) can communicate using a system bus (570). In some implementations, any or all of the components of the computer (500), both hardware or software (or a combination of hardware and software), may interface with each other or the interface (520) (or a combination of both) over the system bus (570) using an application programming interface (API) (550) or a service layer (560) (or a combination of the API (550) and service layer (560). The API (550) may include specifications for routines, data structures, and object classes. The API (550) may be either computer-language independent or dependent and refer to a complete interface, a single function, or even a set of APIs. The service layer (560) provides software services to the computer (500) or other components (whether or not illustrated) that are communicably coupled to the computer (500). The functionality of the computer (500) may be accessible for all service consumers using this service layer. Software services, such as those provided by the service layer (560), provide reusable, defined business functionalities through a defined interface. For example, the interface may be software written in JAVA, C++, or other suitable language providing data in extensible markup language (XML) format or other suitable format. While illustrated as an integrated component of the computer (500), alternative implementations may illustrate the API (550) or the service layer (560) as stand-alone components in relation to other components of the computer (500) or other components (whether or not illustrated) that are communicably coupled to the computer (500). Moreover, any or all parts of the API (550) or the service layer (560) may be implemented as child or sub-modules of another software module, enterprise application, or hardware module without departing from the scope of this disclosure.

The computer (500) includes an interface (520). Although illustrated as a single interface (520) in FIG. 5, two or more interfaces (520) may be used according to particular needs, desires, or particular implementations of the computer (500). The interface (520) is used by the computer (500) for communicating with other systems in a distributed environment that are connected to the network (510). Generally, the interface (520 includes logic encoded in software or hardware (or a combination of software and hardware) and operable to communicate with the network (510). More specifically, the interface (520) may include software supporting one or more communication protocols associated with communications such that the network (510) or interface's hardware is operable to communicate physical signals within and outside of the illustrated computer (500).

The computer (500) includes at least one computer processor (530). Although illustrated as a single computer processor (530) in FIG. 5, two or more processors may be used according to particular needs, desires, or particular implementations of the computer (500). Generally, the computer processor (530) executes instructions and manipulates data to perform the operations of the computer (500) and any algorithms, methods, functions, processes, flows, and procedures as described in the instant disclosure.

The computer (500) also includes a memory (580) that holds data for the computer (500) or other components (or a combination of both) that can be connected to the network (510). For example, memory (580) can be a database storing data consistent with this disclosure. Although illustrated as a single memory (580) in FIG. 5, two or more memories may be used according to particular needs, desires, or particular implementations of the computer (500) and the described functionality. While memory (580) is illustrated as an integral component of the computer (500), in alternative implementations, memory (580) can be external to the computer (500).

The application (540) is an algorithmic software engine providing functionality according to particular needs, desires, or particular implementations of the computer (500), particularly with respect to functionality described in this disclosure. For example, application (540) can serve as one or more components, modules, applications, etc. Further, although illustrated as a single application (540), the application (540) may be implemented as multiple applications (540) on the computer (500). In addition, although illustrated as integral to the computer (500), in alternative implementations, the application (540) can be external to the computer (500).

There may be any number of computers (500) associated with, or external to, a computer system containing computer (500), each computer (500) communicating over network (510). Further, the term “client,” “user,” and other appropriate terminology may be used interchangeably as appropriate without departing from the scope of this disclosure. Moreover, this disclosure contemplates that many users may use one computer (500), or that one user may use multiple computers (500).

In some embodiments, the computer (500) is implemented as part of a cloud computing system. For example, a cloud computing system may include one or more remote servers along with various other cloud components, such as cloud storage units and edge servers. In particular, a cloud computing system may perform one or more computing operations without direct active management by a user device or local computer system. As such, a cloud computing system may have different functions distributed over multiple locations from a central server, which may be performed using one or more Internet connections. More specifically, cloud computing system may operate according to one or more service models, such as infrastructure as a service (IaaS), platform as a service (PaaS), software as a service (SaaS), mobile “backend” as a service (MBaaS), serverless computing, artificial intelligence (AI) as a service (AIaaS), and/or function as a service (FaaS).

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

What is claimed is:

1. A method for predicting true sand resistivity, comprising:
obtaining basic log values of laminated low resistivity sands;
determining, using a computer processor, a volume of solids, a volume of fluids, and first reservoir parameters using a multimineral formation evaluation based on the basic log values of the laminated low resistivity sands;
determining, using the computer processor, a volume of sand, a volume of silt, a volume of clay, and a volume of shale using a silty sand analysis based on the determined volume of solids, the determined volume of fluids, and the first determined reservoir parameters;
inputting, using the computer processor, second determined parameters to a trained machine learning model to determine the true sand resistivity; and
predicting, using the computer processor, the true sand resistivity using the trained machine learning model based on the second determined parameters.

2. The method of claim 1, wherein a volume of hydrocarbon reserves is determined based, at least in part, on the predicted the true sand resistivity.

3. The method of claim 2, wherein a wellbore is designed based on the determined volume of the hydrocarbon reserves.

4. The method of claim 1, wherein the basic logs include basic gamma-ray logs, resistivity logs, density logs, neutron porosity logs, compressional sonic logs, shear sonic logs, and velocity radio logs.

5. The method of claim 1, wherein the second determined parameters include the basic logs of the laminated low resistivity sands, the parameters determined using the multimineral formation evaluation, and the parameters determined using the silty sand analysis.

6. The method of claim 1, wherein the trained machine learning model used to determine the sand resistivity is a Random Forest model based on a best root-mean-square-error.

7. The method of claim 1, wherein the trained machine learning is used for vertical wells from low resistivity high anisotropy zones.

8. A non-transitory computer readable medium storing instructions executable by a computer processor, the instructions comprising functionality for:
obtaining basic log values of laminated low resistivity sands;
determining a volume of solids, a volume of fluids, and first reservoir parameters using a multimineral formation evaluation based on the basic log values of the laminated low resistivity sands;
determining a volume of sand, a volume of silt, a volume of clay, and a volume of shale using a silty sand analysis based on the determined volume of solids, the determined volume of fluids, and the first determined reservoir parameters;
inputting second determined parameters to a trained machine learning model to determine a true sand resistivity; and
determining the true sand resistivity using the trained machine learning model based on the second determined parameters.

9. The non-transitory computer readable medium of claim 8, wherein a volume of hydrocarbon reserves is determined based, at least in part, on the determined true sand resistivity.

10. The non-transitory computer readable medium of claim 9, wherein a wellbore is designed based on the determined volume of the hydrocarbon reserves.

11. The non-transitory computer readable medium of claim 8, wherein the basic logs include basic gamma-ray logs, resistivity logs, density logs, neutron porosity logs, compressional sonic logs, shear sonic logs, and velocity radio logs.

12. The non-transitory computer readable medium of claim 8, wherein the second determined parameters include the basic logs of the laminated low resistivity sands, the parameters determined using the multimineral formation evaluation, and the parameters determined using the silty sand analysis.

13. The non-transitory computer readable medium of claim 8, wherein the trained machine learning model used to determine the sand resistivity is a Random Forest model based on a best root-mean-square-error.

14. A system comprising:
a well logging system; and
a true sand resistivity simulator comprising a computer processor, wherein the true sand resistivity simulator is coupled to the well logging, the true sand resistivity simulator comprising functionality for:
obtaining basic log values of laminated low resistivity sands;
determining a volume of solids, a volume of fluids, and first reservoir parameters using a multimineral formation evaluation based on the basic log values of the laminated low resistivity sands;
determining a volume of sand, a volume of silt, a volume of clay, and a volume of shale using a silty sand analysis based on the determined volume of solids, the determined volume of fluids, and the first determined reservoir parameters;
inputting second determined parameters to a trained machine learning model to determine a true sand resistivity; and
determining the true sand resistivity using the trained machine learning model based on the second determined parameters.

15. The system of claim 14, wherein a volume of hydrocarbon reserves is determined based, at least in part, on the determined true sand resistivity.

16. The system of claim 15, wherein a wellbore is designed based on the determined volume of the hydrocarbon reserves.

17. The system of claim 14, wherein the basic logs include basic gamma-ray logs, resistivity logs, density logs, neutron porosity logs, compressional sonic logs, shear sonic logs, and velocity radio logs.

18. The system of claim 14, wherein the second determined parameters include the basic logs of the laminated low resistivity sands, the parameters determined using the multimineral formation evaluation, and the parameters determined using the silty sand analysis.

19. The system of claim 14, wherein the trained machine learning model used to determine the sand resistivity is a Random Forest model based on a best root-mean-square-error.

20. The system of claim 14, wherein the trained machine learning is used for vertical wells from low resistivity high anisotropy zones.
